(19) United States
(12) Patent Application Publication
(10) Pub. No.: US 2026/0005487 A1
(43) Pub. Date: Jan. 1, 2026

(54) OPTICAL SEMICONDUCTOR DEVICE AND METHOD FOR MANUFACTURING OPTICAL SEMICONDUCTOR DEVICE

(71) Applicant: Mitsubishi Electric Corporation, Tokyo (JP)

(72) Inventor: Kazuyuki ONOE, Tokyo (JP)

(73) Assignee: Mitsubishi Electric Corporation, Tokyo (JP)

(21) Appl. No.: 18/993,129

(22) PCT Filed: Nov. 30, 2022
(86) PCT No.: PCT/JP2022/044082

§ 371 Date: Jan. 10, 2025

(51) Int. Cl. H01S 5/026

(52) U.S. Cl. CPC H01S 5/026

(57) ABSTRACT

A semiconductor device includes a semiconductor substrate; an active layer provided on the semiconductor substrate, and configured to generate a laser beam; an optical modulation layer provided on the semiconductor substrate, the optical modulation layer being adjacent to the active layer, and configured to modulate the laser beam; a clad layer provided on the active layer and the optical modulation layer; and a contact layer provided on the clad layer, wherein the optical modulation layer has a first protrusion provided at an end part closer to the active layer, on an upper surface of the optical modulation layer, the clad layer has a second protrusion provided on an upper surface of the clad layer vertically above the first protrusion, and the contact layer is divided by the second protrusion in an optical axis direction of the laser beam.

### FIELD

The present disclosure relates to an optical semiconductor device and a method for manufacturing the optical semiconductor device.

### BACKGROUND

In a mobile communication system and a cloud service in recent years, data traffic has been rapidly increasing. High speed and large quantity processing of enormous data traffic requires a large number of high speed optical semiconductor devices.

For example, PTL 1 discloses an optical semiconductor device in which a semiconductor laser and an optical modulator are integrated on the same semiconductor substrate, and each of the semiconductor laser and the optical modulator includes a contact layer. In such an optical semiconductor device, a low-resistance contact layer as a p-type semiconductor layer is formed on the semiconductor laser and the optical modulator by using an epitaxial growth method. A portion of the contact layer above a connection portion of the semiconductor laser and the optical modulator is removed by etching, thereby forming an isolation trench to divide the contact layer, which suppresses a mutually flowing current.

### Citation List

### Patent Literature

[PTL 1] JP 2000-275460 A

### SUMMARY

### Technical Problem

In the optical semiconductor device disclosed in PTL 1, however, a complicated step of forming the isolation trench between the semiconductor laser and the optical modulator, and filling the isolation trench is necessary. As a result, the number of steps is increased, which inhibits mass production.

The present disclosure has been made to solve the above-described issues, and an object of the present disclosure is to provide an optical semiconductor device in which the contact layer can be divided without increasing the number of steps, and a method for manufacturing the optical semiconductor device.

### Solution to Problem

A semiconductor device according to the disclosure includes a semiconductor substrate; an active layer provided on the semiconductor substrate, and configured to generate a laser beam; an optical modulation layer provided on the semiconductor substrate, the optical modulation layer being adjacent to the active layer, and configured to modulate the laser beam; a clad layer provided on the active layer and the optical modulation layer; and a contact layer provided on the clad layer, wherein the optical modulation layer has a first protrusion provided at an end part closer to the active layer, on an upper surface of the optical modulation layer, the clad layer has a second protrusion provided on an upper surface of the clad layer vertically above the first protrusion, and the contact layer is divided by the second protrusion in an optical axis direction of the laser beam.

A method for manufacturing an optical semiconductor device according to the disclosure includes a step of forming an active layer configured to generate a laser beam, on a semiconductor substrate; a step of forming an insulating film on the active layer; a step of forming an optical modulation layer on the semiconductor substrate by using the insulating film as a selective growth mask, the optical modulation layer being adjacent to the active layer, having a first protrusion at an end part closer to the active layer on an upper surface, and being configured to modulate the laser beam; a step of removing the insulating film; a step of forming a clad layer on the active layer and the optical modulation layer, the clad layer having a second protrusion on an upper surface vertically above the first protrusion; and a step of forming a contact layer on the clad layer, the contact layer being divided by the second protrusion in an optical axis direction of the laser beam.

### Advantageous Effects of Invention

According to the present disclosure, it is possible to provide the optical semiconductor device in which the contact layer can be divided without increasing the number of steps, and the method for manufacturing the optical semiconductor device.

### BRIEF DESCRIPTION OF DRAWINGS

FIG. 1 is a perspective view of an optical semiconductor device according to Embodiment 1.

FIG. 2 is a cross-sectional view of the optical semiconductor device according to Embodiment 1.

FIG. 3 is a cross-sectional view for explaining a method for manufacturing the optical semiconductor device according to Embodiment 1.

FIG. 4 is a cross-sectional view for explaining the method for manufacturing the optical semiconductor device according to Embodiment 1.

FIG. 5 is a cross-sectional view for explaining the method for manufacturing the optical semiconductor device according to Embodiment 1.

FIG. 6 is a cross-sectional view for explaining the method for manufacturing the optical semiconductor device according to Embodiment 1.

FIG. 7 is a cross-sectional view for explaining the method for manufacturing the optical semiconductor device according to Embodiment 1.

FIG. 8 is a cross-sectional view for explaining the method for manufacturing the optical semiconductor device according to Embodiment 1.

FIG. 9 is a cross-sectional view for explaining the method for manufacturing the optical semiconductor device according to Embodiment 1.

FIG. 10 is a cross-sectional view of an optical semiconductor device according to Embodiment 2.

FIG. 11 is a cross-sectional view for explaining a method for manufacturing the optical semiconductor device according to Embodiment 2.

FIG. 12 is a cross-sectional view of an optical semiconductor device according to Embodiment 3.

FIG. 13 is a cross-sectional view for explaining a method for manufacturing the optical semiconductor device according to Embodiment 3.

FIG. 14 is a cross-sectional view for explaining the method for manufacturing the optical semiconductor device according to Embodiment 3.

FIG. 15 is a cross-sectional view of an optical semiconductor device according to Embodiment 4.

FIG. 16 is a cross-sectional view for explaining a method for manufacturing the optical semiconductor device according to Embodiment 4.

### DESCRIPTION OF EMBODIMENTS

### Embodiment 1

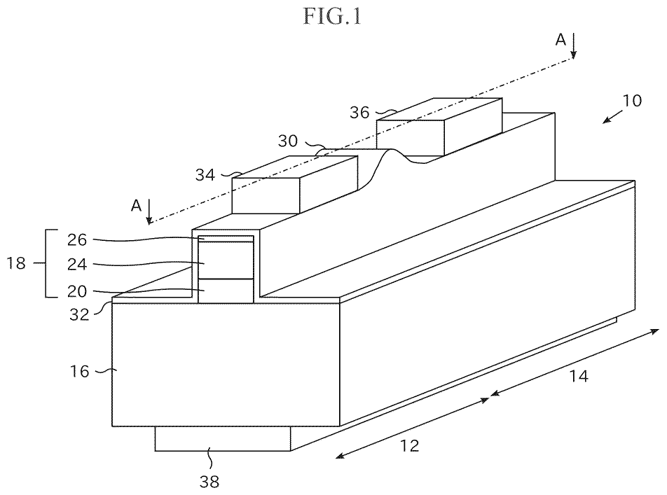

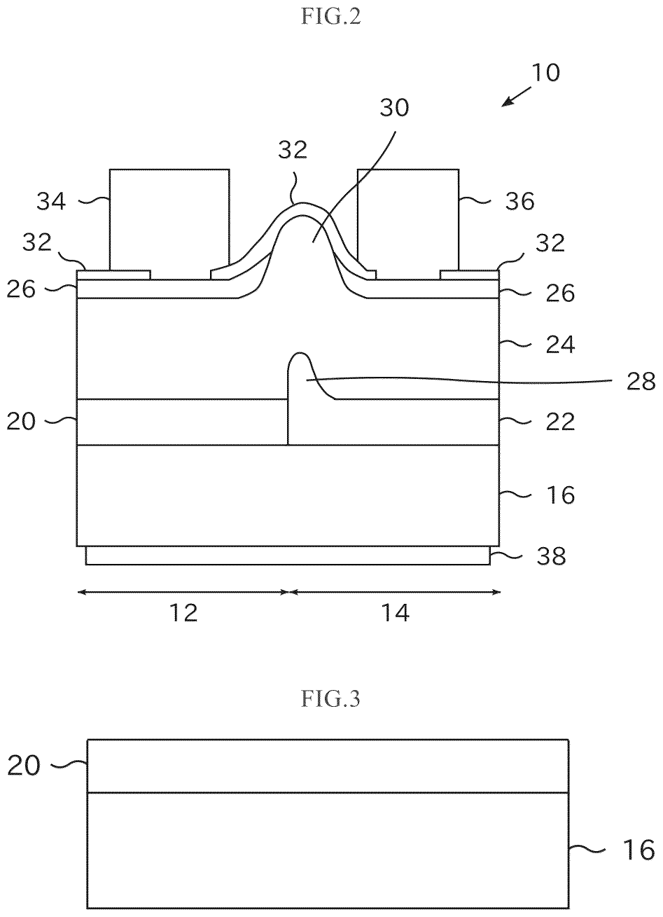

FIG. 1 is a perspective view of an optical semiconductor device 10 according to Embodiment 1. FIG. 2 illustrates a cross-section taken along line A-A in FIG. 1. The optical semiconductor device 10 is a ridge semiconductor laser with an optical modulator, and includes a laser portion 12 and a modulator portion 14 adjacent to the laser portion 12. In the optical semiconductor device 10, a mesa portion 18 having a stripe shape is provided from the laser portion 12 to the modulator portion 14. In the laser portion 12, the mesa portion 18 includes an active layer 20, a clad layer 24, and a contact layer 26, whereas in the modulator portion 14, the mesa portion 18 includes an optical modulation layer 22, the clad layer 24, and the contact layer 26. The active layer 20 of the laser portion 12 generates a laser beam resonated in a stripe direction of the mesa portion 18. The optical modulation layer 22 of the modulator portion 14 modulates the laser beam from the active layer 20 by allowing the laser beam to pass therethrough and absorbing the laser beam. The laser beam modulated by the modulator portion 14 is emitted from an end surface of the mesa portion 18 on the modulator portion 14 side.

The optical semiconductor device 10 includes a semiconductor substrate 16. The semiconductor substrate 16 is made of, for example, n-type InP.

The active layer 20 is provided on the semiconductor substrate 16. The active layer 20 is made of, for example, InP, and includes a strained multiple quantum well structure. By the structure, the laser beam output from the optical semiconductor device 10 can be increased in output and reduced in distortion.

The optical modulation layer 22 is provided adjacently to the active layer 20 on the semiconductor substrate 16. The optical modulation layer 22 is made of, for example, InGaAsP, and includes a quantum well structure. The optical modulation layer 22 has a first protrusion 28 provided at an end part closer to the active layer 20, on an upper surface of the optical modulation layer 22. The first protrusion 28 protrudes up to a position higher than an upper surface of the active layer 20.

The clad layer 24 is provided on the active layer 20 and the optical modulation layer 22. The clad layer 24 is made of, for example, p-type InP doped with Zn, has a p-type concentration of 1×10¹⁸ cm⁻³, and has a thickness of 1 μm. A second protrusion 30 is provided on an upper surface of the clad layer 24. The second protrusion 30 is provided vertically above the first protrusion 28. “Vertical” used herein indicates a direction vertical to an upper surface of the semiconductor substrate 16.

The contact layer 26 is provided on the clad layer 24. The contact layer 26 is made of, for example, p-type InP doped with Zn, has a p-type concentration of 1×10¹⁹ cm⁻³, and has a thickness of 400 nm. The contact layer 26 is divided by the second protrusion 30 in an optical axis direction of the laser beam (right-left direction in FIG. 2). A height of the second protrusion 30 is greater than or equal to the thickness of the contact layer 26 in order to enhance electrical isolation of the divided contact layers 26. The thickness of the contact layer 26 is desirably 400 nm or more in order to cause a current to uniformly flow through the active layer 20 and the optical modulation layer 22, and to maintain a carrier concentration of the contact layer 26 itself.

A protective film 32 that covers an upper surface and side surfaces of the mesa portion 18 and the upper surface of the semiconductor substrate 16 is provided. The protective film 32 on the upper surface of the mesa portion 18 includes an opening for each of the laser portion 12 and the modulator portion 14. A laser electrode 34 and a modulator electrode 36 electrically connected to the respective contact layers 26 through the respective openings are provided. These electrodes are made of, for example, Ti/Pt/Au in order from the bottom. A rear surface electrode 38 is provided on a rear surface of the semiconductor substrate 16. The rear surface electrode 38 is made of, for example, Au/Ge/Ni/Au in order from the semiconductor substrate 16 side.

A method for manufacturing the optical semiconductor device 10 is described.

First, as illustrated in FIG. 3, the active layer 20 is formed on the semiconductor substrate 16. For example, a MOCVD (Metal Organic Chemical Vapor Deposition) method is used for formation.

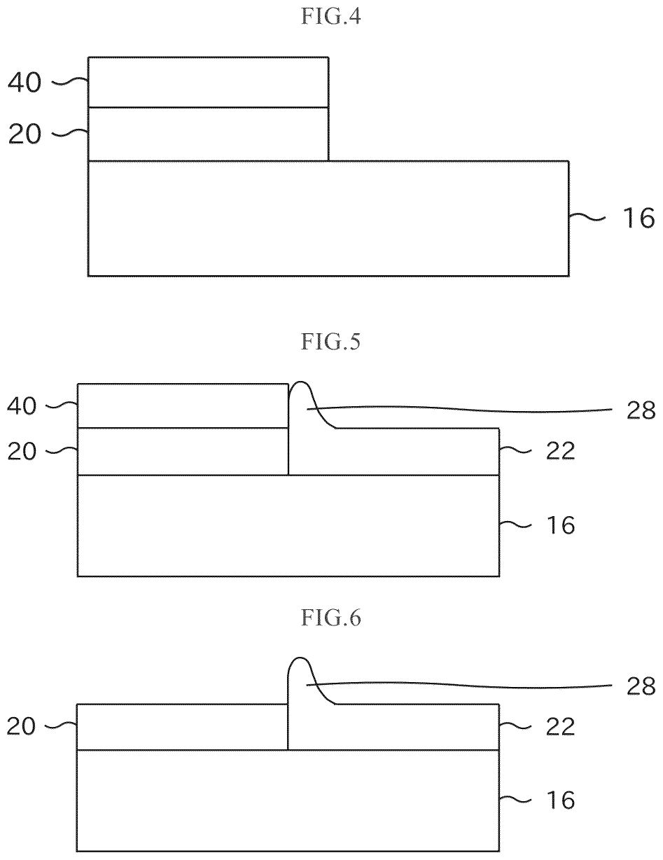

Thereafter, dry etching such as RIE (Reactive Ion Etching) is performed on the active layer 20 up to the semiconductor substrate 16 by using an insulating film 40 formed in a stripe shape on the active layer 20 as an etching mask. As a result, a structure illustrated in FIG. 4 is obtained. The insulating film 40 is made of, for example, SiO₂, and is formed using a sputtering method and a photolithography technique.

Thereafter, as illustrated in FIG. 5, the optical modulation layer 22 is formed on the semiconductor substrate 16 so as to be embedded, by the MOCVD method by using the insulating film 40 as a selective growth mask. During formation of the optical modulation layer 22, part of raw material gas flowing onto the insulating film 40 flows toward the optical modulation layer 22 (right side in FIG. 5). Therefore, overgrowth occurs at the end part on the active layer 20 side in the optical modulation layer 22. As a result, the first protrusion 28 is formed in the optical modulation layer 22.

Thereafter, as illustrated in FIG. 6, the insulating film 40 is removed.

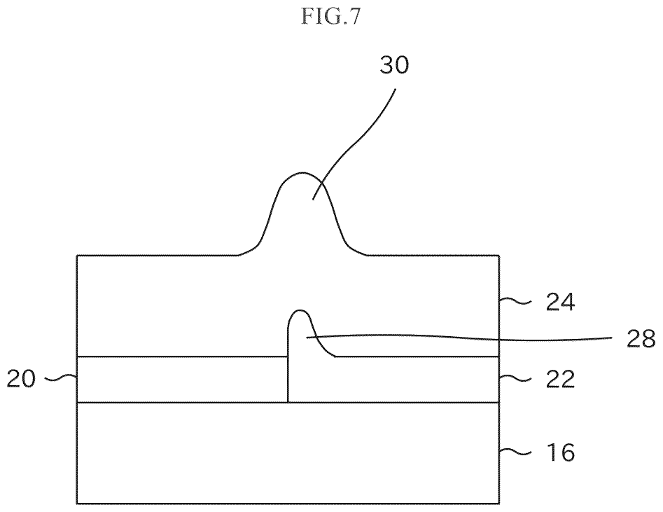

Thereafter, as illustrated in FIG. 7, the clad layer 24 is formed on the active layer 20 and the optical modulation layer 22. For example, the MOCVD method is used for formation. At this time, the second protrusion 30 is formed in the clad layer 24 vertically above the first protrusion 28.

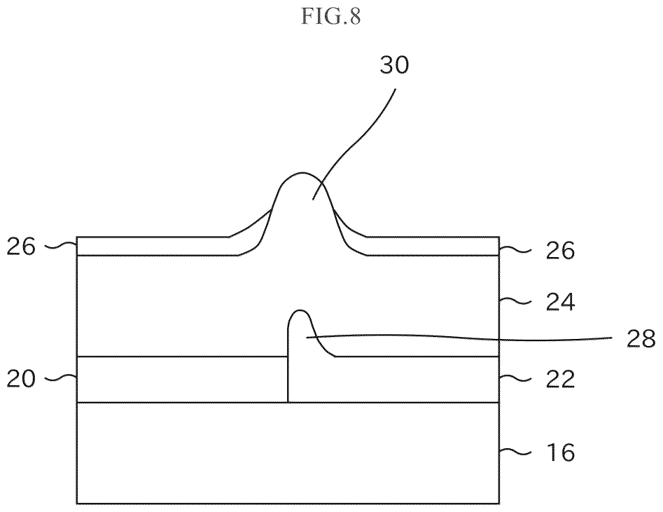

Thereafter, as illustrated in FIG. 8, the contact layer 26 is formed on the clad layer 24 by using the MOCVD method. At this time, the contact layer 26 is grown while chlorine gas (for example, HCl) is added. As a result, the contact layer 26 is grown while a growth layer formed on the second protrusion 30 is shaved. Thus, the contact layer 26 is formed while being divided in the optical axis direction of the laser beam. A range of a growth temperature is 550° C. to 650° C. Since the contact layer 26 is grown under high temperature, an effect of mass transport is assisted, and the contact layer 26 is not grown on the upper surface of the second protrusion 30 relative to a 111B plane. Note that FIG. 8 illustrates a state where the contact layer 26 is not grown anywhere on the upper surface of the second protrusion 30, but the contact layer 26 may be grown at an uppermost part. However, the contact layer 26 is not grown at right and left inclined parts of the second protrusion 30. Thus, the fact remains that the contact layer 26 is divided by the second protrusion 30 in the right-left direction.

Thereafter, a mesa insulating film is formed on the clad layer 24 and the contact layer 26 by a plasma CVD (Chemical Vapor Deposition) method, is patterned into a stripe shape by a transfer process, and is dry etched. Thereafter, the contact layer 26, the clad layer 24, the active layer 20, and the optical modulation layer 22 are dry etched up to the substrate, with chlorine gas by an ICP (Inductively Coupled Plasma) apparatus by using the mesa insulating film as a mask, to form the mesa portion 18 having the stripe shape.

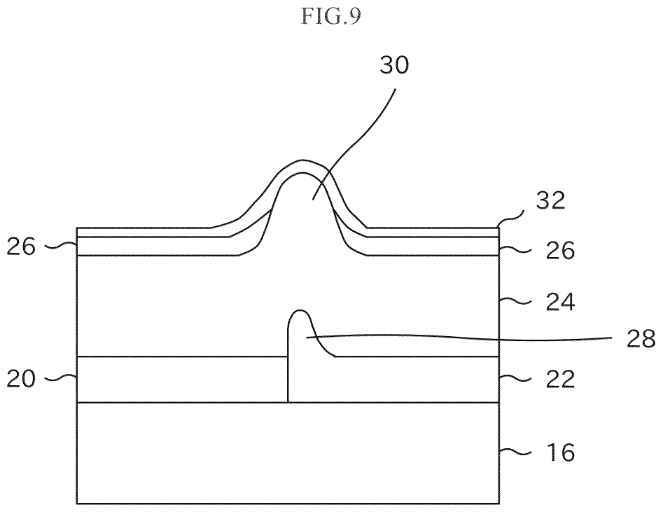

After the mesa insulating film is removed, the protective film 32 is then deposited on the second protrusion 30 and the contact layer 26 (and the side surfaces of the mesa portion 18 and the semiconductor substrate 16) as illustrated in FIG. 9. Thereafter, openings are formed in the protective film 32 in each of the laser portion 12 and the modulator portion 14 by using a transfer process. Thereafter, the laser electrode 34 and the modulator electrode 36 are formed in the respective openings. Thereafter, the rear surface electrode 38 is formed on the rear surface of the semiconductor substrate 16. Thereafter, a resultant body is cleaved at a right angle to the optical axis direction of the laser beam, and a cleavage surface is coated, which results in the optical semiconductor device 10.

As described above, according to the present embodiment, since the second protrusion 30 is provided, it is possible to simultaneously perform growth and division of the contact layer 26 in a MOCVD apparatus. Therefore, the contact layer 26 can be divided without increasing the number of steps.

### Embodiment 2

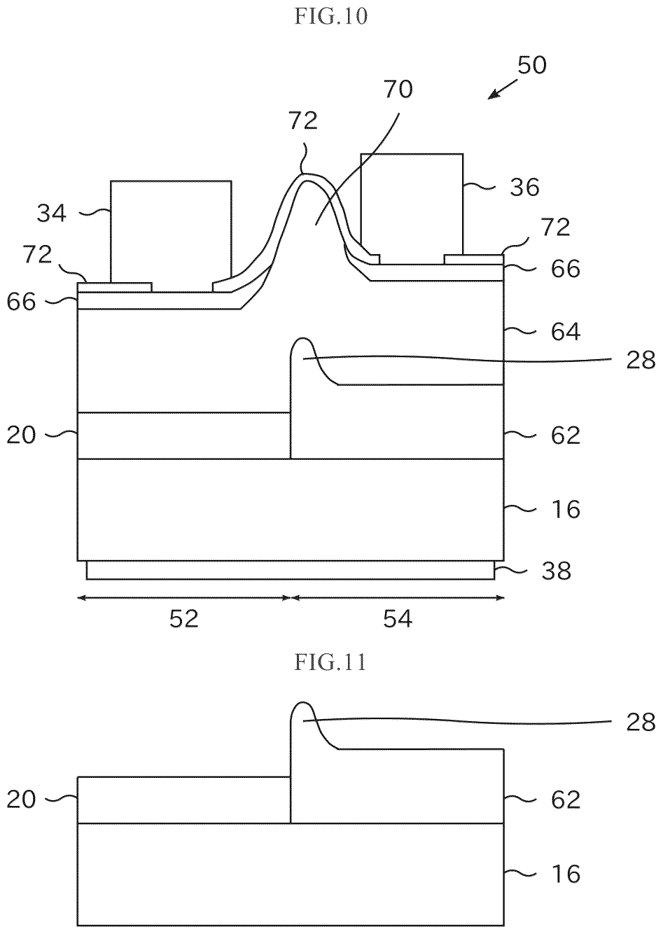

FIG. 10 illustrates a cross-section of an optical semiconductor device 50 according to Embodiment 2. Unlike Embodiment 1, an optical modulation layer 62 of the optical semiconductor device 50 is entirely increased in thickness in addition to a vicinity of a connection portion with the active layer 20. In other words, an upper surface of the optical modulation layer 62 is positioned higher than the upper surface of the active layer 20 at any position.

A method for manufacturing the optical semiconductor device 50 up to the step of performing dry etching on the active layer 20 up to the semiconductor substrate 16 (the step illustrated in FIG. 4) is not different from the method according to Embodiment 1. After the step illustrated in FIG. 4, the optical modulation layer 62 is formed such that the upper surface of the optical modulation layer 62 is positioned higher than the upper surface of the active layer 20 at any position, which results in a structure illustrated in FIG. 11. Subsequent manufacturing steps are similar to the steps according to Embodiment 1.

When the optical modulation layer 62 is made thick as described above, production variation of the optical modulation layer 62 in the height direction can be accommodated in addition to the effects described in Embodiment 1.

### Embodiment 3

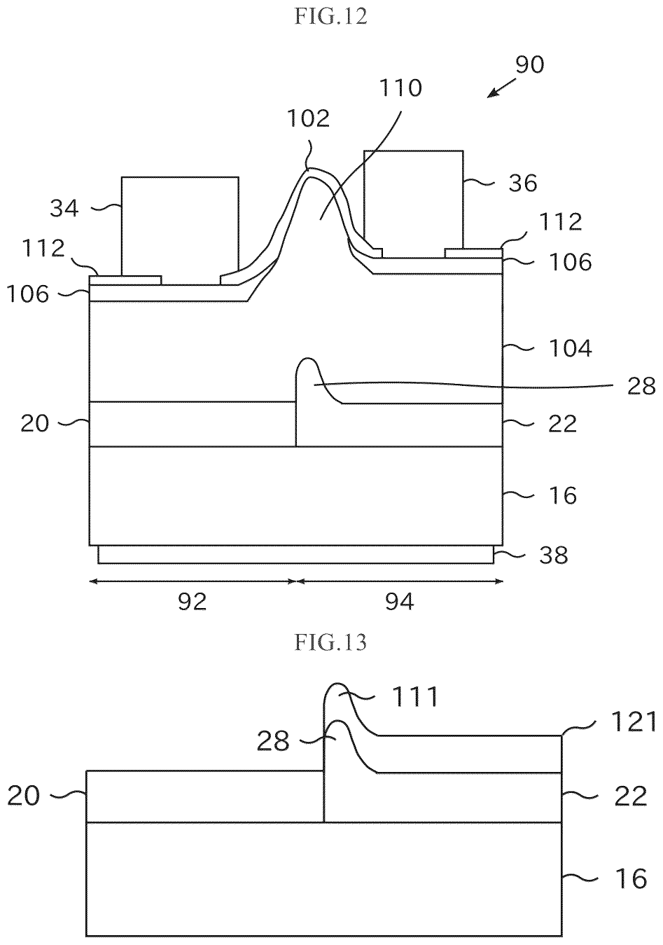

FIG. 12 illustrates a cross-section of an optical semiconductor device 90 according to Embodiment 3. Unlike Embodiment 1, in the optical semiconductor device 90, a portion of a clad layer 104 above the optical modulation layer 22 is thicker than a portion of the clad layer 104 above the active layer 20.

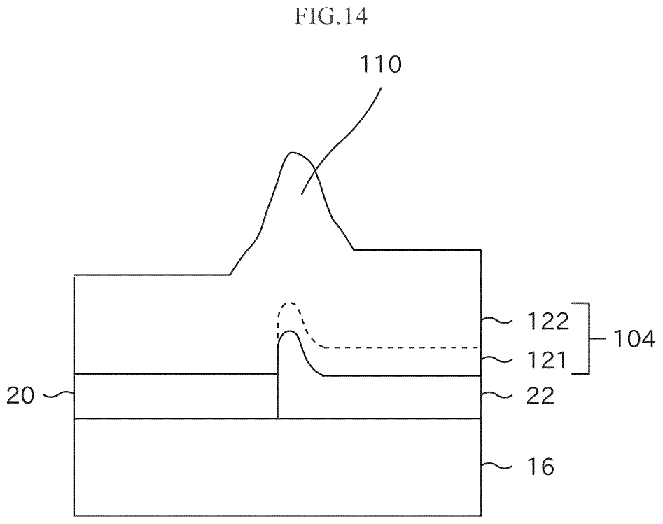

A method for manufacturing the optical semiconductor device 90 up to the step of removing the insulating film 40 (the step illustrated in FIG. 6) is not different from the method according to Embodiment 1. After the step illustrated in FIG. 6, a first clad layer 121 including a third protrusion 111 vertically above the first protrusion 28 is formed on the optical modulation layer 22, which results in a structure illustrated in FIG. 13. Thereafter, as illustrated in FIG. 14, a second clad layer 122 is formed on the active layer 20 and the first clad layer 121. The second clad layer 122 includes the third protrusion 111. A combination of the first clad layer 121 and the second clad layer 122 is the clad layer 104. Subsequent manufacturing steps are similar to the steps according to Embodiment 1.

When the thickness of the clad layer 104 in a modulator portion 94 is increased as described above, a distance between a contact layer 106 formed with a high carrier concentration and the optical modulation layer 22 is increased. Thus, loss of the light is reduced and optical output is increased, in addition to the effects described in Embodiment 1. Further, disorder of a shape (far-field pattern) of the emitted laser beam is small.

The features of Embodiment 3 may be added to Embodiment 2.

### Embodiment 4

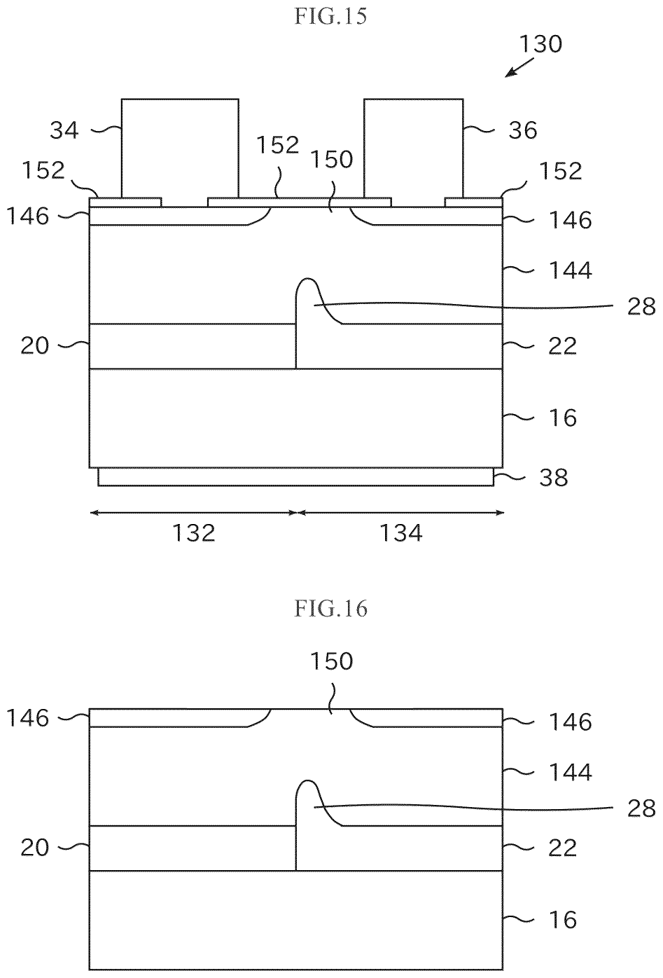

FIG. 15 illustrates a cross-section of an optical semiconductor device 130 according to Embodiment 4. Unlike Embodiment 1, in the optical semiconductor device 130, an upper surface of a second protrusion 150 and an upper surface of a contact layer 146 are positioned on the same plane.

A method for manufacturing the optical semiconductor device 130 up to the step of growing the contact layer 26 (the step illustrated in FIG. 8) is not different from the method according to Embodiment 1. After the step illustrated in FIG. 8, the second protrusion 150 and the contact layer 146 are planarized by performing wet etching using liquid containing Br, which results in a structure illustrated in FIG. 16. Subsequent manufacturing steps are similar to the steps according to Embodiment 1.

When the second protrusion 150 and the contact layer 146 are planarized as described above, a leakage current and a parasitic capacitance can be reduced in addition to the effects described in Embodiment 1. In the present embodiment, a height of the second protrusion 150 is reduced, and an area of a side surface of the second protrusion 150 is reduced. Therefore, a leakage current flowing from the side surface of the second protrusion 150 on a laser portion 132 side to a modulator portion 134, and a leakage current flowing from the side surface of the second protrusion 150 on the modulator portion 134 side to the laser portion 132 are reduced. In the present embodiment, since the area of the side surface of the second protrusion 150 is reduced, a parasitic capacitance of a P-I-N (I means Intrinsic) structure including a clad layer 144, the optical modulation layer 22, and the semiconductor substrate 16 is reduced.

In all of the embodiments, the semiconductor substrate may be of a p-type. In this case, the clad layer and the contact layer are of an n-type. The optical semiconductor device is not limited to the ridge semiconductor laser, and may be an embedded laser.

### Reference Signs List

10, 50, 90, 130 optical semiconductor device, 16 semiconductor substrate, 20 active layer, 22, 62 optical modulation layer, 24, 64, 104 clad layer, 26, 66, 106, 146 contact layer, 28 first protrusion, 30, 70, 110, 150 second protrusion, 40 insulating film, 111 third protrusion, 121 first clad layer, 122 second clad layer

1. An optical semiconductor device, comprising:
a semiconductor substrate;
an active layer provided on the semiconductor substrate, and configured to generate a laser beam;
an optical modulation layer provided on the semiconductor substrate, the optical modulation layer being adjacent to the active layer, and configured to modulate the laser beam;
a clad layer provided on the active layer and the optical modulation layer; and
a contact layer provided on the clad layer, wherein
the optical modulation layer has a first protrusion provided at an end part closer to the active layer, on an upper surface of the optical modulation layer,
the clad layer has a second protrusion provided on an upper surface of the clad layer vertically above the first protrusion,
the contact layer is divided by the second protrusion in an optical axis direction of the laser beam, and
the clad layer is directly over the active layer, and the cladding layer is a single layer.

2. The optical semiconductor device according to claim 1, wherein the upper surface of the optical modulation layer is positioned higher than an upper surface of the active layer at any position.

3. The optical semiconductor device according to claim 1, wherein a portion of the clad layer above the optical modulation layer is thicker than a portion of the clad layer above the active layer.

4. The optical semiconductor device according to claim 1, wherein an upper surface of the second protrusion and an upper surface of the contact layer are positioned on a same plane.

5. A method for manufacturing an optical semiconductor device, the method comprising:
forming an active layer configured to generate a laser beam, on a semiconductor substrate;
forming an insulating film on the active layer;
forming an optical modulation layer on the semiconductor substrate by using the insulating film as a selective growth mask, the optical modulation layer being adjacent to the active layer, having a first protrusion at an end part closer to the active layer on an upper surface, and being configured to modulate the laser beam;
removing the insulating film;
forming a clad layer on the active layer and the optical modulation layer, the clad layer having a second protrusion on an upper surface vertically above the first protrusion and being a single layer; and
forming a contact layer on the clad layer, the contact layer being divided by the second protrusion in an optical axis direction of the laser beam, wherein
in the forming the clad layer, the clad layer is formed so that the clad layer is located directly over the active layer.

6. The method for manufacturing the optical semiconductor device according to claim 5, wherein, in the forming the optical modulation layer, the optical modulation layer is formed to position the upper surface of the optical modulation layer higher than an upper surface of the active layer at any position.

7. A method for manufacturing an optical semiconductor device, the method comprising:
forming an active layer configured to generate a laser beam, on a semiconductor substrate;
forming an insulating film on the active layer;
forming an optical modulation layer on the semiconductor substrate by using the insulating film as a selective growth mask, the optical modulation layer being adjacent to the active layer, having a first protrusion at an end part closer to the active layer on an upper surface, and being configured to modulate the laser beam;
removing the insulating film;
forming a clad layer on the active layer and the optical modulation layer, the clad layer having a second protrusion on an upper surface vertically above the first protrusion; and
forming a contact layer on the clad layer, the contact layer being divided by the second protrusion in an optical axis direction of the laser beam, wherein,
in the forming the clad layer, after a first clad layer including a third protrusion vertically above the first protrusion is formed on the optical modulation layer, a second clad layer is formed on the active layer and the first clad layer to form the clad layer including the first clad layer and the second clad layer.

8. A method for manufacturing an optical semiconductor device, the method comprising:
forming an active layer configured to generate a laser beam, on a semiconductor substrate;
forming an insulating film on the active layer;
forming an optical modulation layer on the semiconductor substrate by using the insulating film as a selective growth mask, the optical modulation layer being adjacent to the active layer, having a first protrusion at an end part closer to the active layer on an upper surface, and being configured to modulate the laser beam;
removing the insulating film;
forming a clad layer on the active layer and the optical modulation layer, the clad layer having a second protrusion on an upper surface vertically above the first protrusion;
forming a contact layer on the clad layer, the contact layer being divided by the second protrusion in an optical axis direction of the laser beam, and
after the forming the contact layer, planarizing an upper surface of the second protrusion and an upper surface of the contact layer by performing wet etching using liquid containing Br, to position the upper surface of the second protrusion and the upper surface of the contact layer on a same plane.

9. The method for manufacturing the optical semiconductor device according to claim 5, wherein, in the forming the contact layer, the contact layer is formed while chlorine gas is added.
